(19) United States
(12) Patent Application Publication
(10) Pub. No.: US 2025/0350133 A1
(43) Pub. Date: Nov. 13, 2025

(54) CHARGING DEVICE

(71) Applicant: LG ELECTRONICS INC., Seoul (KR)

(72) Inventors: Cheolhong PARK, Seoul (KR); Suk KO, Seoul (KR); Kangsuk LEE, Seoul (KR); Sunghwan OH, Seoul (KR); Myoungku LEE, Seoul (KR)

(73) Assignee: LG ELECTRONICS INC., Seoul (KR)

(21) Appl. No.: 18/752,528

(22) Filed: Jun. 24, 2024

(30) Foreign Application Priority Data
May 8, 2024 (KR) 10-2024-0060445

(51) Int. Cl. H02J 7/00; B60L 53/31; F21V 3/00; F21Y 113/00; F21Y 115/10

(52) U.S. Cl. CPC H02J 7/0047; B60L 53/31; F21V 3/00; H02J 7/0042; F21Y 2113/00; F21Y 2115/10

(57) ABSTRACT

Disclosed is a charging device including a main body where a charger connected to a cable is located, a printed circuit board located in the main body and including an LED array mounted on a front surface thereof, a front cover covering the front surface of the printed circuit board, coupled to the main body, and having a seating portion defined in a front surface thereof, and a display cover seated in the seating portion, wherein the seating portion includes a guide hole exposing the LED array such that light output from the LED array is irradiated to the display cover. The charging device uses LED lighting to indicate a charged state, thereby securing visibility and improving a convenience of a user.

### CROSS-REFERENCE TO RELATED APPLICATION(S)

Pursuant to 35 U.S.C. § 119, this application claims the benefit of earlier filing date and right of priority to Korean Application No(s). 10-2024-0060445, filed on May 8, 2024, the contents of which are all incorporated by reference herein in its entirety.

### BACKGROUND

### Field

The present disclosure relates to a charging device that may improve convenience of a user as well as ensure visibility by indicating a charged state using LED lighting.

### Discussion of the Related Art

In general, an electric vehicle (EV) has not been put into practical use for a long time because of problems such as a great weight of a battery mounted in the vehicle and a time it takes to charge when compared to a gasoline or diesel vehicle. However, recently, because of a depletion of fossil energy and environmental pollution, interest in the electric vehicle that does not use the fossil energy but uses electric energy has increased, and research and development on the electric vehicle have been actively conducted.

As a result, popularization of the electric vehicle has been increasing recently. The electric vehicle has a battery that supplies power for operation thereof, and has a structure in which the power is stored in the battery. Therefore, to continuously operate the electric vehicle, the battery must be charged. Accordingly, an infrastructure for charging the electric vehicle is needed, and fixed standing charging facilities are being established in various locations to meet an increasing demand for the electric vehicle.

In this regard, a charging device of the electric vehicle is an element for building a stable charging infrastructure that maintains electrical stability and long-term lifespan. This is because the charging device of the electric vehicle is mainly installed outdoors, such as a parking lot of a public building or a park, a highway rest area, and an apartment complex.

In addition, in a case of the electric vehicle that requires frequent charging, it is necessary to ensure visibility of the charging device even at night for convenience of a user. Additionally, to further improve the convenience of the user, a means to easily check a charged state of the electric vehicle is also needed.

### SUMMARY

The present disclosure relates to a charging device, and more particularly, is to provide a charging device that uses LED lighting to indicate a charged state, thereby securing visibility and improving a convenience of a user.

In addition, the present disclosure is to provide a charging device that may maintain electrical stability and long-term lifespan thereof even when being installed outdoors and exposed to an external environment.

Technical challenges to be solved in the present disclosure are not limited to the technical challenges mentioned above, and other technical challenges not mentioned are able to be clearly understood by those skilled in the art in the technical field to which the present disclosure belongs from a description below.

Provided is a charging device including a main body where a charger connected to a cable is located, a printed circuit board located in the main body and including an LED array mounted on a front surface thereof, a front cover covering the front surface of the printed circuit board, coupled to the main body, and having a seating portion defined in a front surface thereof, and a display cover seated in the seating portion, wherein the seating portion includes a guide hole exposing the LED array such that light output from the LED array is irradiated to the display cover.

In one implementation, the charging device may further include a diffuser plate coupled to a rear surface of the display cover and covering the guide hole, and the diffuser plate may include a plurality of holes defined to allow light output from the LED array to pass therethrough.

In one implementation, the display cover may include a translucent light-transmissive material.

In one implementation, the display cover may include a display area processed corresponding to a location of the diffuser plate, in a front surface thereof.

In one implementation, the charging device may further include a fixing member coupled to the seating portion to expose the guide hole, wherein a rear surface of the diffuser plate is coupled to the fixing member.

In one implementation, the LED array may be disposed in a curved shape on the printed circuit board.

In one implementation, the guide hole may be defined in a curved shape corresponding to the disposition shape of the LED array.

In one implementation, the display cover may include a sealing groove defined along an edge of a rear surface thereof, and the charging device may further include a sealing member inserted into the sealing groove and filling a gap between the display cover and the seating portion.

In one implementation, the charging device may further include a driver connected to the printed circuit board to turn on the LED array, and the driver may change a lighting color of the LED array.

In one implementation, the driver may change a lighting area of the LED array.

In one implementation, the charging device may further include a display that is located in the main body and outputs an image, the seating portion may include a first exposure hole exposing the display, and the display cover may include a second exposure hole defined at a location corresponding to the first exposure hole.

In one implementation, the charging device may further include a sound device that is located in the main body and outputs audio, the seating portion may include a third exposure hole exposing the sound device, and the display cover may include a fourth exposure hole defined at a location corresponding to the third exposure hole.

In one implementation, the charging device may further include an optical cover including a lower portion located on top of the main body and a side portion extending upward from an edge of the lower portion, and a sealing cover coupled to a top surface of the side portion of the optical cover.

In one implementation, the charging device may further include a printed circuit board located on a top surface of the lower portion of the optical cover to be spaced apart from an inner surface of the side portion of the optical cover, wherein an LED array is mounted on a top surface of the printed circuit board, and the optical cover may include a translucent light-transmissive material such that light output from the LED array mounted on the top surface of the printed circuit board is irradiated through the side portion.

In one implementation, the charging device may further include a light guide member coupled to the top surface of the lower portion of the optical cover and located between the inner surface of the side portion and the LED array.

The charging device according to the present disclosure may use the LED lighting to indicate the charged state, thereby securing the visibility and improving the convenience of the user.

In addition, even when the charging device is installed outdoors and exposed to the external environment, the electrical stability and the long-term lifespan thereof may be maintained.

Effects that may be obtained from the present disclosure are not limited to the effects mentioned above, and other effects not mentioned are able to be clearly understood by those skilled in the art in the technical field to which the present disclosure belongs from a description below.

### BRIEF DESCRIPTION OF THE DRAWINGS

FIG. 1 is a front view of a charging device according to an embodiment of the present disclosure.

FIG. 2 is an exploded view of a configuration located in front of a main body in a charging device according to an embodiment of the present disclosure.

FIG. 3 is a diagram showing a diffuser plate in a charging device according to an embodiment of the present disclosure.

FIG. 4 is a diagram showing a front surface of a display cover in a charging device according to an embodiment of the present disclosure.

FIG. 5 is a diagram showing a rear surface of a display cover in a charging device according to an embodiment of the present disclosure.

FIG. 6 is a cross-sectional view taken along a line A-A in FIG. 1.

FIG. 7 is an exploded view of a configuration located on a main body in a charging device according to an embodiment of the present disclosure.

FIG. 8 is a diagram showing an optical cover in a charging device according to an embodiment of the present disclosure.

FIG. 9 is a diagram showing a bottom surface of a sealing cover in a charging device according to an embodiment of the present disclosure.

FIG. 10 is a cross-sectional view taken along a line B-B in FIG. 1.

### DESCRIPTION OF SPECIFIC EMBODIMENTS

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

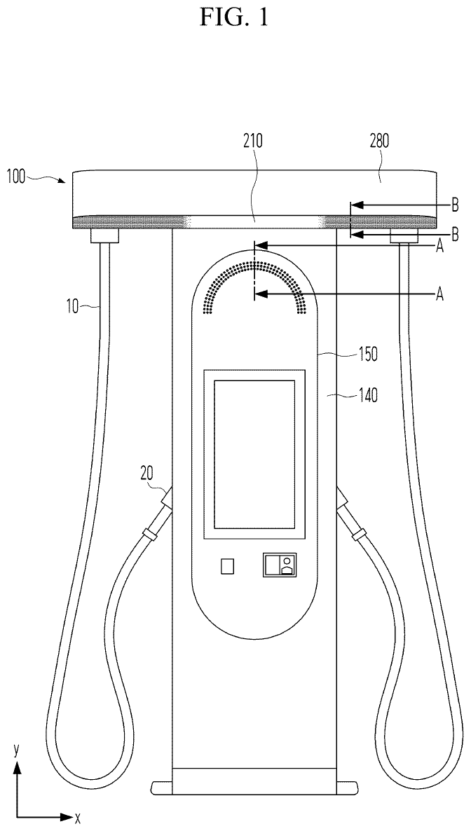

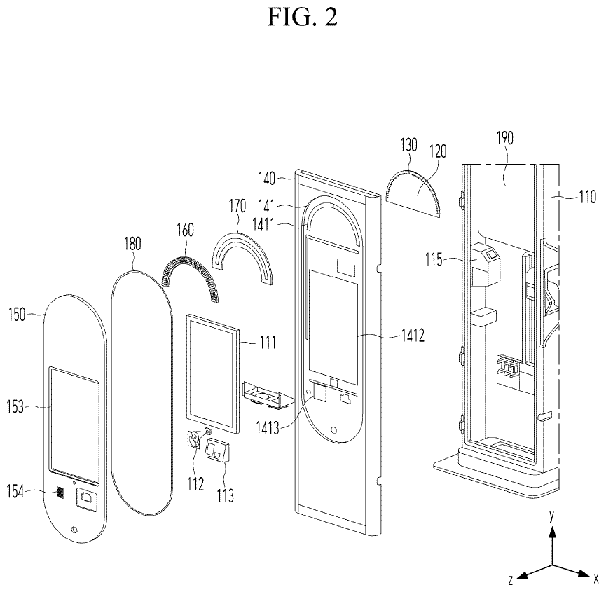

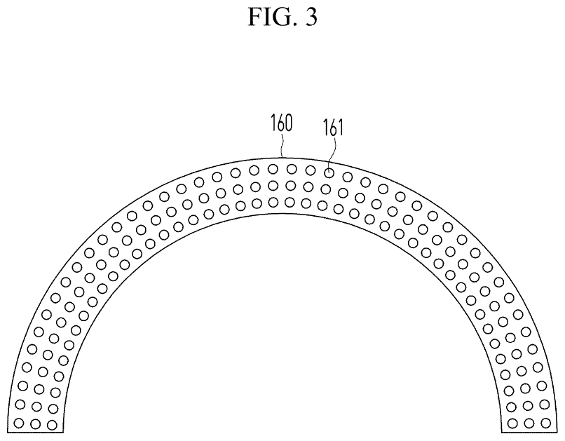

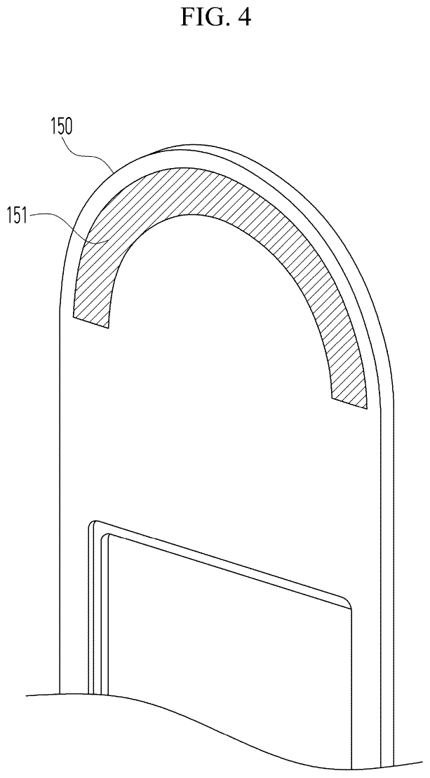

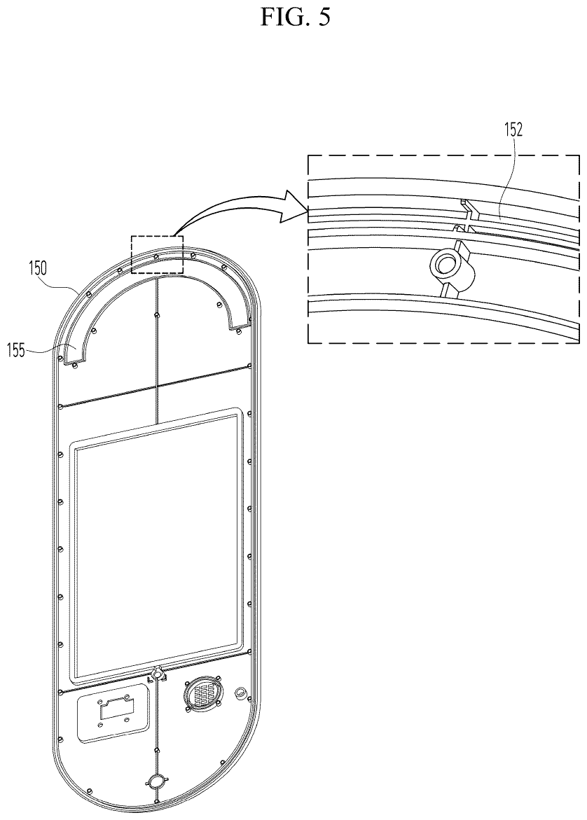

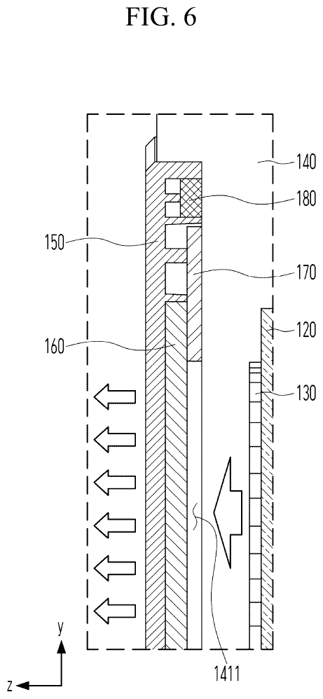

FIG. 1 is a front view of a charging device 100 according to an embodiment of the present disclosure. FIG. 2 is an exploded view of a configuration located in front of a main body 110 in the charging device 100 according to an embodiment of the present disclosure. FIG. 3 is a diagram showing a diffuser plate 160 in the charging device 100 according to an embodiment of the present disclosure. FIG. 4 is a diagram showing a front surface of a display cover 150 in the charging device 100 according to an embodiment of the present disclosure. FIG. 5 is a diagram showing a rear surface of the display cover 150 in the charging device 100 according to an embodiment of the present disclosure. Further, FIG. 6 is a cross-sectional view taken along a line A-A in FIG. 1.

Hereinafter, in describing the charging device 100 according to an embodiment of the present disclosure, a left and right direction will be described based on an x-axis direction, a vertical direction will be described based on a y-axis direction, and a front and rear direction will be described based on a z-axis direction.

Referring to FIGS. 1 and 2 together, the charging device 100 according to an embodiment of the present disclosure may include the main body 110, a printed circuit board 120, an LED array 130, a front cover 140, and the display cover 150. First, a charger 20 to which a cable 10 for charging an electric vehicle (EV) is connected may be located on the main body 110. A holder 115 to position the charger 20 may be formed on a side surface of the main body 110. Additionally, the printed circuit board 120 may be located in the main body 110, and the LED array 130 may be mounted on a front surface of the printed circuit board 120. Accordingly, the LED array 130 may be turned on via the printed circuit board 120.

The front cover 140 may cover the front surface of the printed circuit board 120 and may be coupled to the main body 110. Additionally, a seating portion 141 may be formed in a front surface of the front cover 140. In this regard, the seating portion 141 may be defined in a form of a groove recessed inward from the front surface of the front cover 140. Further, the display cover 150 may be seated in the seating portion 141 defined in the front surface of the front cover 140.

In particular, in the charging device 100 according to an embodiment of the present disclosure, the seating portion 141 defined in the front surface of the front cover 140 may include a guide hole 1411 that exposes the LED array 130 such that light output from the LED array 130 is irradiated to the display cover 150. Accordingly, the guide hole 1411 may be at least defined in a shape that corresponds to a disposition shape of the LED array 130 such that the LED array 130 may be exposed.

For example, in the charging device 100 according to an embodiment of the present disclosure, the LED array 130 may be disposed in a curved shape on the printed circuit board 120. In this regard, the guide hole 1411 may be formed in a curved shape such that the LED array 130 may be exposed.

Additionally, referring to FIG. 3, the charging device 100 according to an embodiment of the present disclosure may include the diffuser plate 160 that is coupled to the rear surface of the display cover 150 and covers the guide hole 1411. Additionally, the diffuser plate 160 may include a plurality of holes 161 defined to allow light output from the LED array 130 to pass therethrough. In other words, the diffuser plate 160 may play a role in allowing light output from the LED array 130 to form an image that is irradiated to the display cover 150 in a form shown in FIG. 1.

Accordingly, in the charging device 100 according to an embodiment of the present disclosure, the diffuser plate 160 may be formed in a shape corresponding to the disposition shape of the LED array 130. Additionally, the plurality of holes 161 defined in the diffuser plate 160 may be defined in a shape corresponding to the disposition shape of the LED array 130. In addition, the plurality of holes 161 may be formed in a form that corresponds to the image in which light irradiated from the LED array 130 is emitted to the display cover 150. That is, for example, as shown in FIG. 3, the plurality of holes 161 may be formed in the diffuser plate 160 in a form of three rows, allowing the irradiated image as shown in FIG. 1 to be formed.

Additionally, referring to FIG. 5, a fastening groove 155 may be defined in the rear surface of the display cover 150, and the diffuser plate 160 may be seated in the fastening groove 155. Further, as shown in FIG. 6, light irradiated from the LED array 130 may pass through the diffuser plate 160 to form the image irradiated onto the display cover 150.

Additionally, in the charging device 100 according to an embodiment of the present disclosure, the display cover 150 may include a translucent light-transmissive material. Further, as shown in FIG. 4, the display cover 150 may include a display area 151 processed corresponding to the location of the diffuser plate 160 on the front surface. For example, after painting the front surface of the display cover 150, cutting using a laser may be performed on the display area 151. This is to ensure that an internal configuration of the charging device 100 is not visible in the display area 151 when the LED array 130 is not turned on. In other words, by processing the display area 151 of the display cover 150, the front surface of the display cover 150 may be viewed in an integrated manner when the LED array 130 is not turned on.

Additionally, the charging device 100 according to an embodiment of the present disclosure may further include a fixing member 170 that is coupled to the seating portion 141 to expose the guide hole 1411 and is coupled to a rear surface of the diffuser plate 160. In this regard, the fixing member 170 may be formed in a shape corresponding to the formation of the guide hole 1411 and the shape of the diffuser plate 160 based on the disposition shape of the LED array 130.

Furthermore, referring to FIG. 2 together, the charging device 100 according to an embodiment of the present disclosure may include a driver 190 that is connected to the printed circuit board 120 and turns on the LED array 130. Further, the driver 190 may change a lighting color of the LED array 130. Additionally, the driver 190 may change a lighting area of the LED array 130.

This is because, as described above, in the case of the electric vehicle that requires frequent charging, visibility of the charging device 100 needs to be secured even at night for convenience of a user. Additionally, this is because, to further improve the convenience of the user, a means to easily check a charged state of the electric vehicle is also needed.

In other words, the charging device 100 according to an embodiment of the present disclosure may change the lighting color of the LED array 130 via the driver 190 by distinguishing between a charging standby state, a charging state, a charging completed state, a charging unavailable state, and the like. For example, the lighting color of the LED array 130 may be blue in the charging standby state, the lighting color of the LED array 130 may be green in the charging state, and the lighting color of the LED array 130 may be red in the charging completed state or the charging unavailable state. Accordingly, the convenience of the user may be improved.

In addition, the charging device 100 according to an embodiment of the present disclosure may change the lighting area of the LED array 130 via the driver 190. For example, LEDs of the LED array 130 may be turned on sequentially from left to right, from center to both sides, or from the both sides to the center.

Additionally, referring to FIGS. 2 and 5 together, in the charging device 100 according to an embodiment of the present disclosure, the display cover 150 may include a sealing groove 152 defined along an edge of the rear surface thereof. Further, the charging device 100 of the present disclosure may further include a sealing member 180 that is inserted into the sealing groove 152 and fills a gap between the display cover 150 and the seating portion 141. In this regard, the sealing member 180 may include, for example, a rubber member made of silicon.

This is because, as mentioned above, the charging device 100 is exposed to an external environment because of a nature thereof of being mainly installed outdoors, and in particular, a means for waterproofing is necessary to maintain electrical stability and long-term life of the charging device 100.

Therefore, the charging device 100 according to an embodiment of the present disclosure fills the gap that may occur when the display cover 150 is seated in the seating portion 141 via the sealing member 180 that is inserted into the sealing groove 152, thereby securing the electrical stability or the like via a waterproof structure.

Additionally, referring to FIG. 2, the charging device 100 according to an embodiment of the present disclosure may include a display 111 that is located in the main body 110 and outputs an image. Additionally, the seating portion 141 may include a first exposure hole 1412 that exposes the display 111 located in the main body 110. As described above, in the charging device 100 according to an embodiment of the present disclosure, the display cover 150 may include the translucent light-transmissive material. Accordingly, the image output via the display 111 may be viewed via the display cover 150.

In addition, in the charging device 100 according to an embodiment of the present disclosure, the display cover 150 may include a second exposure hole 153 defined at a location corresponding to the first exposure hole 1412. Accordingly, a front surface of the display 111 may be exposed via the second exposure hole 153, so that the image output via the display 111 may be viewed.

In this regard, the display 111 may realize a touch screen by constituting a mutual layer structure or being integrated with a touch sensor. Such touch screen may serve to provide an input interface between the charging device 100 and the user, and at the same time, provide an output interface between the charging device 100 and the user.

In addition, referring to FIG. 2, the charging device 100 according to an embodiment of the present disclosure may include a sound device 112 that is located in the main body 110 and outputs audio. Further, the seating portion 141 may include a third exposure hole 1413 that exposes the sound device 112, and the display cover 150 may include a fourth exposure hole 154 defined at a location corresponding to the third exposure hole 1413.

In this regard, the sound device 112 may serve to provide sound information on the charging standby state, the charging state, the charging completed state, the charging unavailable state, and the like of the charging device 100 described above to the user.

Additionally, referring to FIG. 2, the charging device 100 according to an embodiment of the present disclosure may be equipped with a card terminal 113. For example, the user may charge the electric vehicle via the charging device 100 of the present disclosure by inserting a card, which is a payment method, into the card terminal 113 and then making the payment.

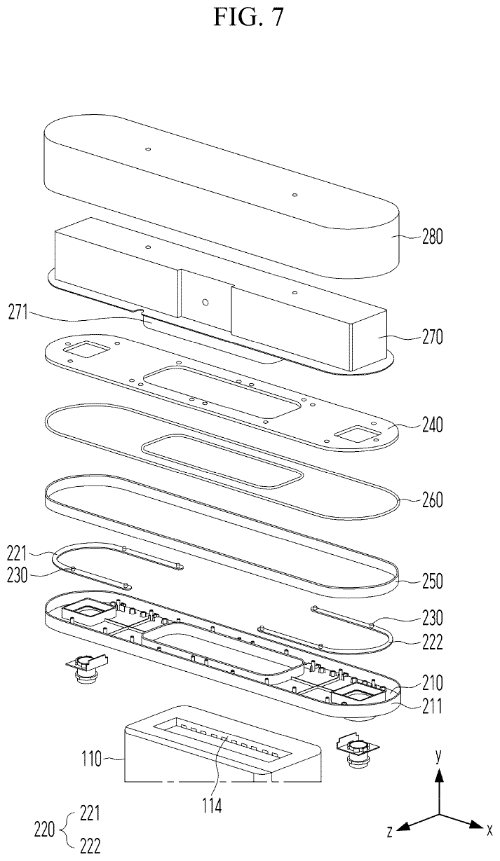

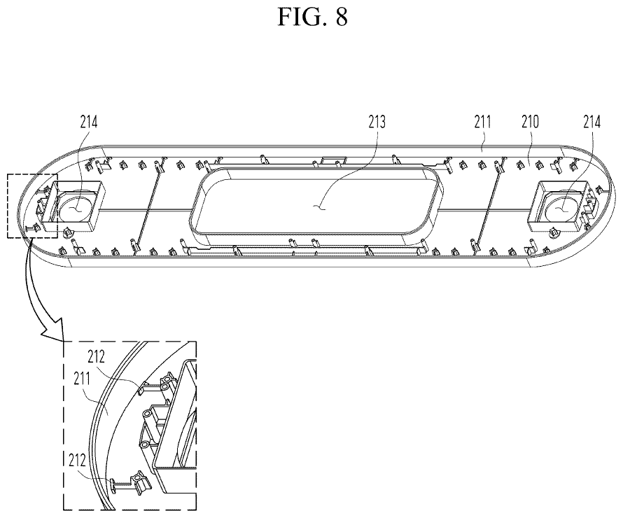

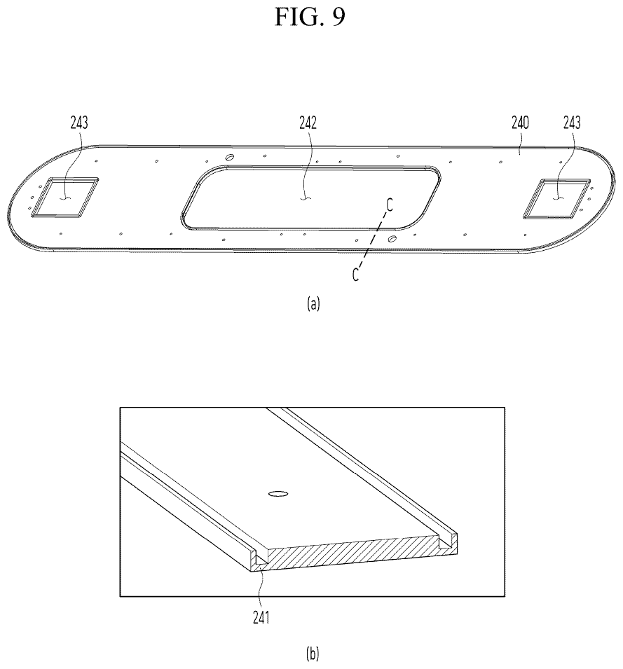

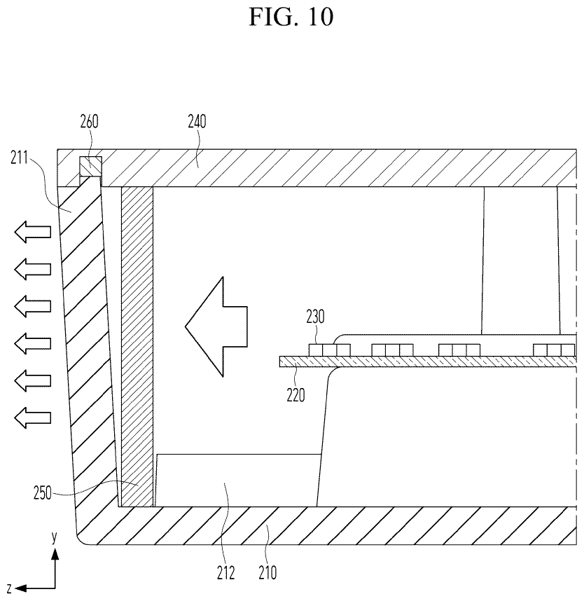

FIG. 7 is an exploded view of a configuration located on the main body 110 in the charging device 100 according to an embodiment of the present disclosure. FIG. 8 is a diagram showing an optical cover 210 in the charging device 100 according to an embodiment of the present disclosure. FIG. 9 is a diagram showing a bottom surface of a sealing cover 240 in the charging device 100 according to an embodiment of the present disclosure. Further, FIG. 10 is a cross-sectional view taken along a line B-B in FIG. 1.

Referring to FIGS. 1 and 7 together, the charging device 100 according to an embodiment of the present disclosure may include the optical cover 210, a printed circuit board 220, and the sealing cover 240 located on the main body 110. The optical cover 210 may have a lower portion located on top of the main body 110 and include a side portion 211 extending upward from an edge of the lower portion. In addition, the printed circuit board 220 may be located on a top surface of the lower portion of the optical cover 210, spaced apart from an inner surface of the side portion 211 of the optical cover 210, and may mount an LED array 230 thereon. Accordingly, the LED array 230 may be turned on via the printed circuit board 220. The sealing cover 240 may cover the printed circuit board 220 and may be coupled to a top surface of the side portion 211.

In particular, in the charging device 100 according to an embodiment of the present disclosure, the optical cover 210 may include a translucent light-transmissive material such that light output from the LED array 230 is irradiated via the side portion 211.

Further, the charging device 100 according to an embodiment of the present disclosure may include a light guide member 250 coupled to the top surface of the lower portion of the optical cover 210 and positioned between the inner surface of the side portion 211 and the LED array 230. In this regard, the light guide member 250 may include a strap shape facing the inner surface of the side portion 211. Additionally, a front surface of the light guide member 250 may be formed in a flat planar shape.

That is, light output from the LED array 230 may be diffused as shown in FIG. 10 while passing through the light guide member 250. Accordingly, the light guide member 250 may serve to form an image projected onto the optical cover 210 as shown in FIG. 1.

In addition, referring to FIG. 8, in the charging device 100 according to an embodiment of the present disclosure, the optical cover 210 may include a guide rib 212 that is formed on the top surface of the lower portion thereof to be spaced apart from the inner surface of the side portion 211, and fixes the light guide member 250. That is, the light guide member 250 may be coupled and fixed in a form of being inserted between the inner surface of the side portion 211 and the guide rib 212 of the optical cover 210.

In addition, referring to FIGS. 8 and 10 together, the guide rib 212 may be formed to extend inwards of the optical cover 210, and the printed circuit board 220 may extend and be disposed on the guide rib 212 formed to extend. Additionally, light output from the LED array 230 mounted on the printed circuit board 220 may be irradiated toward the light guide member 250.

Referring again to FIG. 7, in the charging device 100 according to an embodiment of the present disclosure, the printed circuit board 220 may be a flexible printed circuit board (FPCB). Further, the printed circuit board 220 may include a strap shape curved along the inner surface of the side portion 211 of the optical cover 210. Additionally, the printed circuit board 220 may include a first printed circuit board 221 and a second printed circuit board 222 that are positioned spaced apart from each other in a left and right direction (an x-axis direction) with respect to a center of the optical cover 210. Accordingly, an irradiated image as shown in FIG. 1 may be formed on a front portion, a side portion, and a rear portion of each of both sides of the optical cover 210.

In addition, the charging device 100 according to an embodiment of the present disclosure may include a driver 270 that is located on the sealing cover 240 and is connected to the printed circuit board 220 to turn on the LED array 230. In this regard, the driver 270 may play a role in changing a lighting color of the LED array 230. Additionally, the driver 270 may play a role in changing a lighting area of the LED array 230.

This is because, as described above, in the case of the electric vehicle that requires the frequent charging, the visibility of the charging device 100 needs to be secured even at night for the convenience of the user. Additionally, this is because, to further improve the convenience of the user, the means to easily check the charged state of the electric vehicle is also needed.

That is, the charging device 100 according to an embodiment of the present disclosure may change the lighting color of the LED array 230 via the driver 270 by distinguishing between the charging standby state, the charging state, the charging completed state, the charging unavailable state, and the like. For example, the lighting color of the LED array 230 may be blue in the charging standby state, the lighting color of the LED array 230 may be green in the charging state, and the lighting color of the LED array 230 may be red in the charging completed state or the charging unavailable state. Accordingly, the convenience of the user may be improved.

In addition, the charging device 100 according to an embodiment of the present disclosure may change the lighting area of the LED array 230 via the driver 270. For example, LEDs of the LED array 230 mounted on the above-described first printed circuit board 221 and LEDs of the LED array 230 mounted on the above-described second printed circuit board 222 may be turned on in an alternating manner or may be turned on sequentially from left to right or right to left. Additionally, based on the first printed circuit board 221 and the second printed circuit board 222, the LEDs may be turned on sequentially from a center to both sides or from the both sides to the center.

In summary, as shown in FIG. 1, the charging device 100 according to an embodiment of the present disclosure may form the LED-irradiated image via the display cover 150 located at the front side of the main body 110 or form the LED-irradiated image via the optical cover 210 located on the main body 110 and indicate the charged state, thereby securing the visibility and improving the convenience of the user.

(a) in FIG. 9 is a diagram showing a bottom surface of the sealing cover 240 in the charging device 100 according to an embodiment of the present disclosure. Further, (b) in FIG. 9 is a perspective view including a cross-section taken along a line C-C in (a) in FIG. 9.

Additionally, as shown in FIG. 9, in the charging device 100 according to an embodiment of the present disclosure, the sealing cover 240 may include a sealing groove 241 defined along an edge of the bottom surface thereof. Further, referring to FIGS. 7 and 10 together, the charging device 100 of the present disclosure may further include a sealing member 260 that is inserted into the sealing groove 241 and fills a gap between the sealing cover 240 and the top surface of the side portion 211 of the optical cover 210. In this regard, the sealing member 260 may include, for example, a rubber member made of silicon.

This is because, as mentioned above, the charging device 100 is exposed to the external environment because of the nature thereof of being mainly installed outdoors, and in particular, the means for the waterproofing is necessary to maintain the electrical stability and the long-term life of the charging device 100.

Therefore, the charging device 100 according to an embodiment of the present disclosure may fill the gap that may occur when the sealing cover 240 is coupled to the top surface of the side portion 211 of the optical cover 210 via the sealing member 260 that is inserted into the sealing groove 241, thereby securing the electrical stability or the like via the waterproof structure.

Additionally, as shown in FIG. 7, in the charging device 100 according to an embodiment of the present disclosure, the driver 270 may include a connection terminal 271 protruding from a bottom thereof. Additionally, the main body 110 may include a connector 114 formed at a top thereof and to which the connection terminal 271 is coupled. That is, the connection terminal 271 may be coupled to the connector 114 of the main body 110, and the driver 270 may be operated.

Accordingly, referring to FIGS. 8 and 9 together, in the charging device 100 according to an embodiment of the present disclosure, the sealing cover 240 may include a first receiving hole 242 into which the connection terminal 271 is inserted. In addition, the optical cover 210 may include a second receiving hole 213 defined corresponding to a location of the first receiving hole 242 and into which the connection terminal 271 is inserted.

Additionally, referring to FIGS. 1 and 7 together, the charging device 100 according to an embodiment of the present disclosure may further include an upper cover 280 that covers the driver 270. That is, the driver 270, which applies an electrical signal to operate the printed circuit board 220, may be protected from the external environment via the upper cover 280. Accordingly, the charging device 100 of the present disclosure may maintain the electrical stability and maintain the long-term lifespan.

Furthermore, as described above with reference to FIG. 1, the charger 20 connected to the cable 10 may be located on the main body 110. Further, as shown in FIGS. 7 to 9, the optical cover 210 may include a first cable hole 214 defined at a bottom thereof and into which the cable 10 is inserted. Additionally, the sealing cover 240 may include a second cable hole 243 defined corresponding to a location of the first cable hole 214. Accordingly, the cable 10 may be connected to the driver 270 via the first cable hole 214 and the second cable hole 243.

Summarizing the above, the charging device according to the present disclosure may use the LED lighting to indicate the charged state, thereby securing the visibility and improving the convenience of the user. In addition, even when the charging device is installed outdoors and exposed to the external environment, the electrical stability and the long-term lifespan thereof may be maintained.

The above detailed description is to be construed in all aspects as illustrative and not restrictive. The scope of the present disclosure should be determined by reasonable interpretation of the appended claims and all changes coming within the equivalency range of the present disclosure are intended to be embraced in the scope of the present disclosure.

What is claimed is:

1. A charging device comprising:
a main body where a charger connected to a cable is located;
a printed circuit board located in the main body and including an LED array mounted on a front surface thereof;
a front cover covering the front surface of the printed circuit board, coupled to the main body, and having a seating portion defined in a front surface thereof; and
a display cover seated in the seating portion,
wherein the seating portion includes a guide hole exposing the LED array such that light output from the LED array is irradiated to the display cover.

2. The charging device of claim 1, further comprising a diffuser plate coupled to a rear surface of the display cover and covering the guide hole,
wherein the diffuser plate includes a plurality of holes defined to allow light output from the LED array to pass therethrough.

3. The charging device of claim 2, wherein the display cover includes a translucent light-transmissive material.

4. The charging device of claim 3, wherein the display cover includes a display area processed corresponding to a location of the diffuser plate, in a front surface thereof.

5. The charging device of claim 2, further comprising a fixing member coupled to the seating portion to expose the guide hole, wherein a rear surface of the diffuser plate is coupled to the fixing member.

6. The charging device of claim 1, wherein the LED array is disposed in a curved shape on the printed circuit board.

7. The charging device of claim 6, wherein the guide hole is defined in a curved shape corresponding to the disposition shape of the LED array.

8. The charging device of claim 1, wherein the display cover includes a sealing groove defined along an edge of a rear surface thereof,
wherein the charging device further includes a sealing member inserted into the sealing groove and filling a gap between the display cover and the seating portion.

9. The charging device of claim 1, further comprising a driver connected to the printed circuit board to turn on the LED array,
wherein the driver changes a lighting color of the LED array.

10. The charging device of claim 9, wherein the driver changes a lighting area of the LED array.

11. The charging device of claim 1, further comprising a display located in the main body and configured to output an image,
wherein the seating portion includes a first exposure hole exposing the display,
wherein the display cover includes a second exposure hole defined at a location corresponding to the first exposure hole.

12. The charging device of claim 1, further comprising a sound device located in the main body and configured to output audio,
wherein the seating portion includes a third exposure hole exposing the sound device,
wherein the display cover includes a fourth exposure hole defined at a location corresponding to the third exposure hole.

13. The charging device of claim 1, further comprising:
an optical cover including a lower portion located on top of the main body and a side portion extending upward from an edge of the lower portion; and
a sealing cover coupled to a top surface of the side portion of the optical cover.

14. The charging device of claim 13, further comprising a printed circuit board located on a top surface of the lower portion of the optical cover to be spaced apart from an inner surface of the side portion of the optical cover, wherein an LED array is mounted on a top surface of the printed circuit board,
wherein the optical cover includes a translucent light-transmissive material such that light output from the LED array mounted on the top surface of the printed circuit board is irradiated through the side portion.

15. The charging device of claim 14, further comprising a light guide member coupled to the top surface of the lower portion of the optical cover and located between the inner surface of the side portion and the LED array.
